(19) United States
(12) Patent Application Publication
(10) Pub. No.: US 2026/0293354 A1
(43) Pub. Date: Sep. 24, 2026

(54) IMAGE SENSOR WITH DOUBLE METAL-INSULATOR-METAL CAPACITOR

(71) Applicant: SEMICONDUCTOR COMPONENTS INDUSTRIES, LLC, Scottsdale, AZ (US)

(72) Inventors: Bartosz Piotr BANACHOWICZ, San Jose, CA (US); Vincent James MCGAHAY, Poughkeepsie, NY (US); Jeffrey Peter GAMBINO, Gresham, OR (US)

(73) Assignee: SEMICONDUCTOR COMPONENTS INDUSTRIES, LLC, Scottsdale, AZ (US)

(21) Appl. No.: 19/442,833

(22) Filed: Jan. 7, 2026

Related U.S. Application Data
(60) Provisional application No. 63/774,333, filed on Mar. 19, 2025.

(51) Int. Cl. H10F 39/00; H10W 20/40

(52) U.S. Cl. CPC H10F 39/811; H10W 20/496

(57) ABSTRACT

Double metal-insulator-metal (MIM) capacitors, image sensor pixels, and methods for fabricating double MIM capacitors. The double MIM capacitor includes a trench, a first electrode layer, a first dielectric layer, a second electrode layer, a second dielectric layer, a third electrode layer, a metal spacer layer, and a via. The trench is etched between a side of a dielectric film layer and a first conductive layer. The first electrode layer is formed along an inner border of the trench and extending away from an open end of the trench. The first dielectric layer is formed on the first electrode layer. The second electrode is layer formed on the first dielectric layer. The second dielectric layer is formed on the second electrode layer. The third electrode layer is formed on the second dielectric layer. The metal spacer layer is electrically coupling the first and third electrode layers.

### CROSS-REFERENCE TO RELATED APPLICATIONS

This application claims the benefit of U.S. Provisional Application No. 63/774,333 filed Mar. 19, 2025, and titled “IMAGE SENSOR WITH DOUBLE METAL-INSULATOR-METAL CAPACITOR.” The provisional application is incorporated by reference herein as if reproduced in full below.

### BACKGROUND

Image sensors are used in electronic devices such as cellular telephones, cameras, and computers to capture images. In particular, an electronic device is provided with an array of pixels arranged in a grid pattern. Each pixel receives incident photons, such as light, and converts the photons into electrical signals. Column circuitry is coupled to each column for reading out sensor signals from each pixel.

### SUMMARY

Pixels in image sensors for high dynamic range (HDR) imaging can include a metal-insulator-metal (MIM) capacitor to capture overflow charge resulting from bright regions in a captured scene. Increasing the capacitance available to each pixel provides higher dynamic range detection for the image sensor. For example, a double MIM capacitor can provide almost two times higher capacitive density than a single MIM capacitor. A double MIM capacitor includes a stack of top, middle, and bottom electrodes separated by two dielectric layers. A via can be used to electrically couple the top and bottom electrodes to each other and to a metal layer that is electrically coupled to a floating diffusion. However, vias take up significant space and complicate layout. Thus, the present disclosure provides double MIM capacitors, pixels of image sensors, and methods for fabricating double MIM capacitors in which a metal spacer layer electrically couples the top and bottom electrodes to, among other things, reduce layout size and complexity.

The present disclosure provides a double MIM capacitor for a pixel of an image sensor. The double MIM capacitor includes, in one implementation, a trench, a first electrode layer, a first dielectric layer, a second electrode layer, a second dielectric layer, a third electrode layer, a metal spacer layer, and a via. The trench is etched between a side of a dielectric film layer and a first conductive layer. The first conductive layer is positioned within the dielectric film layer and is electrically coupled to a floating diffusion of the pixel. The first electrode layer is formed along an inner border of the trench and extending away from an open end of the trench along the side of the dielectric film layer. The first dielectric layer is formed on the first electrode layer. The second electrode layer is formed on the first dielectric layer. The second dielectric layer is formed on the second electrode layer. The third electrode layer is formed on the second dielectric layer. The metal spacer layer is electrically coupling the first electrode layer and the third electrode layer. The via is electrically coupling the second electrode layer and a second conductive layer. The second conductive layer is electrically coupled to a power terminal of the image sensor.

The present disclosure also provides a pixel of an image sensor. The pixel includes, in one implementation, a dielectric film layer, a floating diffusion, a lower conductive layer, an upper conductive layer, and a double MIM capacitor. The lower conductive layer is positioned within the dielectric film layer and electrically coupled to the floating diffusion. The upper conductive layer is electrically coupled to a power terminal. The double MIM capacitor includes, in one implementation, a trench, three stacked electrode layers, two dielectric layers, a metal space layer and a via. The trench is etched between a side of the dielectric film layer and the lower conductive layer. The three stacked electrode layers are formed along an inner border of the trench and extend outward from an open end of the trench along the side of the dielectric film layer. The two dielectric layers separate the three stacked electrode layers. The metal spacer layer electrically couples a top electrode layer and a bottom electrode layer of the three stacked electrode layers. The via is electrically coupling a middle electrode layer of the three stacked electrode layers to the upper conductive layer.

The present disclosure further provides a method for fabricating a double MIM capacitor for a pixel of an image sensor. The method includes etching a trench between a side of a dielectric film layer and a first conductive layer. The first conductive layer is positioned within the dielectric film layer and is electrically coupled to a floating diffusion of the pixel. The method also includes forming a first electrode layer along an inner border of the trench and extending outward from an open end of the trench along the side of the dielectric film layer. The method further includes forming a first dielectric layer on the first electrode layer. The method also includes forming a second electrode layer on the first dielectric layer. The method further includes forming a second dielectric layer on the second electrode layer. The method also includes forming a third electrode layer on the second dielectric layer. The method further includes forming a metal spacer layer that electrically couples the first electrode layer and the third electrode layer. The method also includes forming a via that electrically couples the second electrode layer and a second conductive layer. The second conductive layer is electrically coupled to a power terminal of the image sensor.

### BRIEF DESCRIPTION OF THE DRAWINGS

For a detailed description of example implementations, reference will now be made to the accompanying drawings in which:

FIG. 1 is a block diagram of an example of an imaging system in accordance with some implementations;

FIG. 2 is a diagram of an example of an imaging system incorporated in a vehicle in accordance with some implementations;

FIG. 3 is a partial schematic and a partial block diagram of an example of an image sensor in accordance with some implementations;

FIG. 4 is a schematic of an example of circuitry in a pixel in accordance with some implementations;

FIGS. 5A-5Q are cross-sectional views during different steps of an example of a process for manufacturing a double metal-insulator-metal (MIM) capacitor with a patterned metal spacer layer in accordance with some implementations;

FIGS. 6A-6M are cross-sectional views during different steps of an example of a process for manufacturing a double MIM capacitor with a blanket metal spacer layer in accordance with some implementations; and

FIG. 7 is a flow diagram of an example of a method for fabricating a double MIM capacitors for a pixel of an image sensor in accordance with some implementations.

### DEFINITIONS

Various terms are used to refer to particular system components. Different companies may refer to a component by different names – this document does not intend to distinguish between components that differ in name but not function. In the following discussion and in the claims, the terms “including” and “comprising” are used in an open-ended fashion, and thus should be interpreted to mean “including, but not limited to… .” Also, the term “couple” or “couples” is intended to mean either an indirect or direct connection. Thus, if a first device couples to a second device, that connection may be through a direct connection or through an indirect connection via other devices and connections.

“A”, “an”, and “the” as used herein refer to both singular and plural referents unless the context clearly dictates otherwise. By way of example, “a processor” programmed to perform various functions refers to one processor programmed to perform each and every function, or more than one processor collectively programmed to perform each of the various functions. To be clear, an initial reference to “a [referent]”, and then a later reference for antecedent basis purposes to “the [referent]”, shall not obviate that the recited referent may be plural.

Terms defining an elevation, such as “above,” “below,” “upper”, and “lower” shall be locational terms in reference to a direction of light incident upon a pixel array and/or an image pixel. Light entering shall be considered to interact with or pass objects and/or structures that are “above” and “upper” before interacting with or passing objects and/or structures that are “below” or “lower.” Thus, the locational terms may not have any relationship to the direction of the force of gravity.

“Assert” shall mean creating or maintaining a first predetermined state of a Boolean signal. Boolean signals may be asserted high or with a higher voltage, and Boolean signals may be asserted low or with a lower voltage, at the discretion of the circuit designer. Similarly, “de-assert” shall mean creating or maintaining a second predetermined state of the Boolean, opposite the asserted state.

In relation to electrical devices, whether stand alone or as part of an integrated circuit, the terms “input” and “output” refer to electrical connections to the electrical devices, and shall not be read as verbs requiring action. For example, a differential amplifier, such as an operational amplifier, may have a first differential input and a second differential input, and these “inputs” define electrical connections to the operational amplifier, and shall not be read to require inputting signals to the operation amplifier.

“Controller” shall mean, alone or in combination, individual circuit components, an application specific integrated circuit (ASIC), one or more microcontrollers with controlling software, a reduced-instruction-set computer (RISC) with controlling software, a digital signal processor (DSP), one or more processors with controlling software, a programmable logic device (PLD), a field programmable gate array (FPGA), or a programmable system-on-a-chip (PSOC), configured to read inputs and drive outputs responsive to the inputs.

### DETAILED DESCRIPTION

The following discussion is directed to various implementations of the invention. Although one or more of these implementations may be preferred, the implementations disclosed should not be interpreted, or otherwise used, as limiting the scope of the present disclosure, including the claims. In addition, one skilled in the art will understand that the following description has broad application, and the discussion of any implementation is meant only to be exemplary of that implementation, and not intended to intimate that the scope of the present disclosure, including the claims, is limited to that implementation.

Various examples are directed to double metal-insulator-metal (MIM) capacitors for pixels in image sensors and methods for fabricating double MIM capacitors. More particularly, at least some examples are directed to double MIM capacitors in which a metal spacer layer electrically couples the top and bottom electrodes for small layout size and lower layout complexity. More particularly still, various examples are directed to double MIM capacitors with a trench that lands on a metal layer for lower bottom electrode resistance. The specification now turns to an example system to orient the reader.

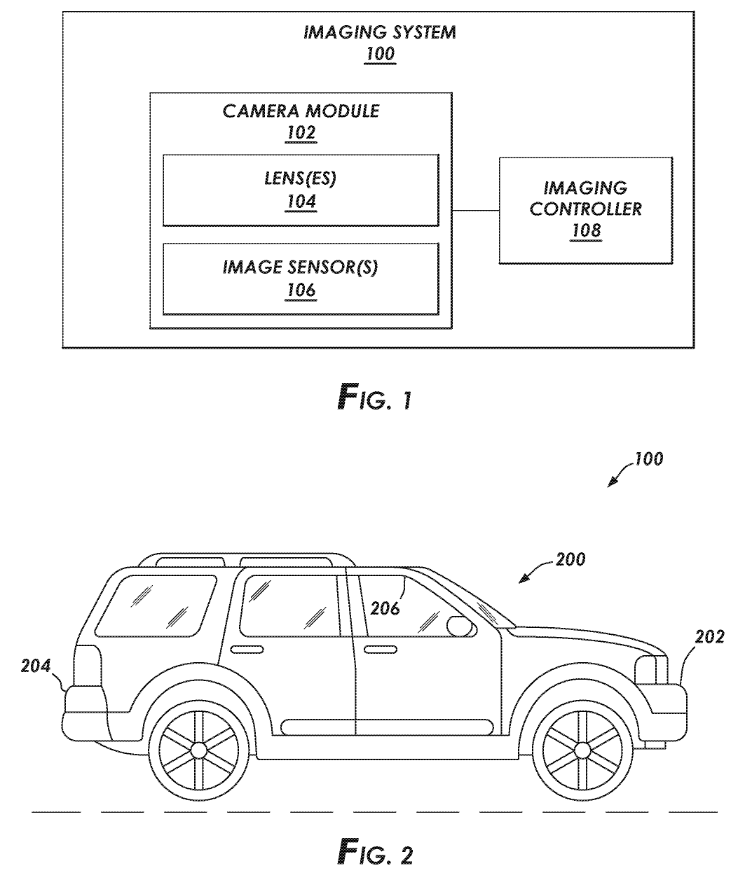

FIG. 1 shows an example of an imaging system 100. In particular, the imaging system 100 may be a portable electronic device such as a camera, a cellular telephone, a tablet computer, a webcam, a video camera, a video surveillance system, or a video gaming system with imaging capabilities. In other cases, the imaging system 100 may be an automotive imaging system. The imaging system 100 illustrated in FIG. 1 includes a camera module 102 that may be used to convert incoming light into digital image data. The camera module 102 may include one or more lenses 104 and one or more corresponding image sensors 106. The lenses 104 may include fixed and/or adjustable lenses. During image capture operations, light from a scene may be focused onto the image sensor 106 by the lenses 104. The image sensor 106 may comprise circuitry for converting analog pixel data into corresponding digital image data to be provided to the imaging controller 108. If desired, the camera module 102 may be provided with an array of lenses 104 and an array of corresponding image sensors 106.

The imaging controller 108 may include one or more integrated circuits. The imaging circuits may include image processing circuits, microprocessors, and storage devices, such as random-access memory, and non-volatile memory. The imaging controller 108 may be implemented using components that are separate from the camera module 102 and/or that form part of the camera module 102, for example, circuits that form part of the image sensor 106. Digital image data captured by the camera module 102 may be processed and stored using the imaging controller 108. Processed image data may, if desired, be provided to external equipment, such as computer, external display, or other device, using wired and/or wireless communications paths coupled to the imaging controller 108.

FIG. 2 shows another example of the imaging system 100. The imaging system 100 shown in FIG. 2 comprises an automobile or vehicle 200. The vehicle 200 is illustratively shown as a passenger vehicle, but the imaging system 100 may be other types of vehicles, including commercial vehicles, on-road vehicles, and off-road vehicles. Commercial vehicles may include buses and tractor-trailer vehicles. Off-road vehicles may include tractors and crop harvesting equipment. In the example of FIG. 2, the vehicle 200 includes a forward-looking camera module 202 arranged to capture images of scenes in front of the vehicle 200. The forward-looking camera module 202 can be used for any suitable purpose, such as lane-keeping assist, collision warning systems, distance-pacing cruise-control systems, autonomous driving systems, and proximity detection. The vehicle 200 further comprises a backward-looking camera module 204 arranged to capture images of scenes behind the vehicle 200. The backward-looking camera module 204 can be used for any suitable purpose, such as collision warning systems, reverse direction video, autonomous driving systems, proximity detection, monitoring position of overtaking vehicles, and backing up. The vehicle 200 further comprises a side-looking camera module 206 arranged to capture images of scenes beside the vehicle 200. The side-looking camera module 206 can be used for any suitable purpose, such as blind-spot monitoring, collision warning systems, autonomous driving systems, monitoring position of overtaking vehicles, lane-change detection, and proximity detection. In situations in which the imaging system 100 is a vehicle, the imaging controller 108 may be a controller of the vehicle 200. The discussion now turns in greater detail to the image sensor 106.

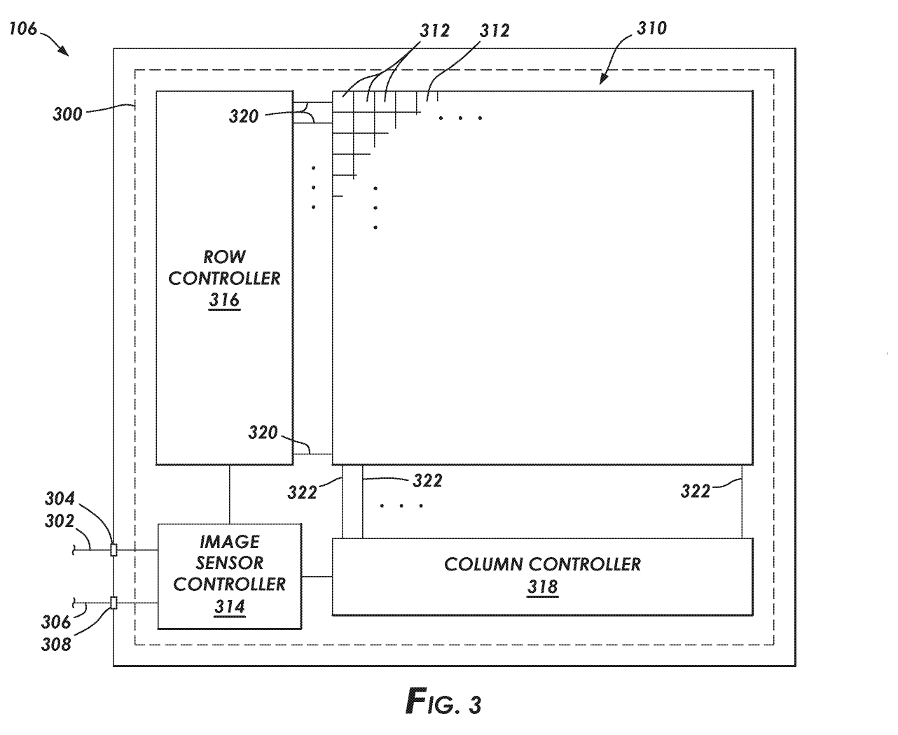

FIG. 3 shows an example of the image sensor 106. In particular, FIG. 3 shows that the image sensor 106 may comprise a substrate 300 of semiconductor material, such as silicon, encapsulated within packaging to create a packaged semiconductor device or packaged semiconductor product. Bond pads or other connection points of the substrate 300 couple to terminals of the image sensor 106. The connections may comprise a serial communication channel 302 coupled to a first terminal 304, and a capture input 306 coupled to a second terminal 308. Additional terminals will be present, such as ground, common, or power, but the additional terminals are omitted so as not to unduly complicate the figure. While a single instance of the substrate 300 is shown, in other implementations, multiple substrates may be combined to form the image sensor 106 in a multi-chip module created before or after singulation.

The image sensor 106 shown in FIG. 3 includes a pixel array 310 with a plurality of pixels, such as pixels 312. The pixel array 310 may include, for example, hundreds or thousands of rows and columns of pixels 312. Control and readout of the pixel array 310 may be implemented by an image sensor controller 314 coupled to a row controller 316 and a column controller 318. The row controller 316 may receive row addresses from the image sensor controller 314 and supply corresponding row control signals to the pixels 312, such as reset, row select, charge transfer, and readout control signals. The row control signals may be communicated over one or more conductors, such as row control paths 320.

The column controller 318 may be coupled to the pixel array 310 by way of one or more conductors, such as column lines 322. Column controllers may sometimes be referred to as column control circuits, readout circuits, or column decoders. The column lines 322 may be used for reading out pixel signals from pixels 312 and for supplying bias currents and/or bias voltages to pixels 312. If desired, during readout operations, a pixel row in the pixel array 310 may be selected using the row controller 316 and pixels signals generated by the pixels 312 in that pixel row can be read out along the column lines 322. The column controller 318 may include sample-and-hold circuitry for sampling and temporarily storing signals read out from the pixel array 310, amplifier circuitry, analog-to-digital conversion (ADC) circuitry, bias circuitry, column memory, latch circuitry for selectively enabling or disabling the column circuitry, or other circuitry that is coupled to one or more columns of pixels 312 in the pixel array 310 for operating the pixels 312 and for reading out pixel signals from the pixel array 310. ADC circuitry in the column controller 318 may convert analog pixel values received from the pixel array 310 into corresponding digital data. The column controller 318 may supply the digital data to the image sensor controller 314 and/or the imaging controller 108 of FIG. 1 over, for example, the serial communication channel 302.

The pixels 312 in the pixel array 310 may include one or more photodiodes, one or more single-photon avalanche detectors (SPADs), one or more silicon photomultipliers (SiPMs), or a combination thereof. FIG. 4 is an electrical schematic of an example of one of the pixels 312 in the pixel array 310. In particular, the pixel 312 shown in FIG. 4 includes a photodetector 402 in the example form of a photodiode, an anti-blooming transistor 404, a transfer transistor 406, a floating diffusion 408, a reset transistor 410, a source-follower transistor 412, a row select transistor 414, a gain control transistor 416, and a double MIM capacitor 418. The photodetector 402 defines an anode coupled to ground or common, and a cathode coupled to the anti-blooming transistor 404 and the transfer transistor 406. The anti-blooming transistor 404 selectively connects the photodetector 402 to a positive pixel power supply voltage, such as supply voltage Vdd. The transfer transistor 406 selectively connects the photodetector 402 to the floating diffusion 408. The reset transistor 410 selectively connects the floating diffusion 408 to the positive pixel power supply voltage. The source-follower transistor 412 buffers a signal associated with charge stored in the floating diffusion 408. The row select transistor 414 selectively connects the source-follower transistor 412 to one of the column lines 322. The gain control transistor 416 selectively connects the floating diffusion 408 to the double MIM capacitor 418. In some implementations, some or all of the pixels 312 in the pixel array 310 may have the same components in the same configuration as the pixel 312 shown in FIG. 4. In other implementations, some or all of the pixels 312 in the pixel array 310 may have fewer components, additional components, or different components in different configurations than the pixel 312 shown in FIG. 4.

Before an image is acquired, the pixel array 310 is reset. For example, an anti-blooming control signal AB may be asserted to reset the pixel array 310. As shown in FIG. 4, the anti-blooming control signal AB is applied to the gate terminal of the anti-blooming transistor 404. Thus, the anti-blooming transistor 404 is made conductive when the anti-blooming control signal AB is asserted. Making the anti-blooming transistor 404 conductive resets the photodetector 402 to a voltage equal or close to the supply voltage Vdd. Further, to reset the pixel array 310, a reset control signal RST may be asserted. As shown in FIG. 4, the reset control signal RST is applied to the gate terminal of the reset transistor 410. Thus, the reset transistor 410 is made conductive when the reset control signal RST is asserted. Making the reset transistor 410 conductive (while the gain control transistor 416 is conductive) resets the floating diffusion 408 to a voltage equal or close to the supply voltage Vdd. After the floating diffusion 408 is reset, the reset control signal RST may be de-asserted to turn off the reset transistor 410.

After the pixel array 310 is reset, the photodetector 402 gathers incoming light during an integration time. The photodetector 402 converts the light to electrical charge. To arrange the pixel array 310 to be sensitive to light during the integration time, the anti-blooming control signal AB may be de-asserted to turn off the anti-blooming transistor 404. After (or during) the integration time, a transfer control signal TX may be asserted. As shown in FIG. 4, the transfer control signal TX is applied to the gate terminal of the transfer transistor 406. Thus, the transfer transistor 406 is made conductive when the transfer control signal TX is asserted. Making the transfer transistor 406 conductive transfers charge generated by the photodetector 402 to the floating diffusion 408. After the charge is transferred to the floating diffusion 408, the transfer control signal TX may be de-asserted to turn off the transfer transistor 406. Next, a row select control signal RS may be asserted. As shown in FIG. 4, the row select control signal RS is applied to the gate terminal of the row select transistor 414. Thus, the row select transistor 414 is made conductive when the row select control signal RS is asserted. Making the row select transistor 414 conductive outputs an output signal Vout that is representative of the magnitude of charge stored in the floating diffusion 408. The output signal Vout is one example of a “pixel signal.” When the row select control signal RS is asserted, one of the column lines 322 can be used to route the output signal Vout to readout circuitry, such as the column controller 318 in FIG. 3. After the output signal Vout is output, the row select control signal RS may be de-asserted to turn off the row select transistor 414.

Bright regions in a captured scene can cause the photodetector 402 to generate more charge than the floating diffusion 408 is capable to store. To reduce saturation for bright regions in a captured scene, a gain control signal G_CTRL may be asserted. As shown in FIG. 4, the gain control signal G_CTRL is applied to the gate terminal of the gain control transistor 416. Thus, the gain control transistor 416 is made conductive when the gain control signal G_CTRL is asserted. Making the gain control transistor 416 conductive allows overflow charge from the photodetector 402 to be collected in the double MIM capacitor 418. The double MIM capacitor 418 provides higher dynamic range detection for the image sensor 106 by increasing the capacitance available for each of the pixels 312. However, the increased capacitance decreases the voltage of the signal provided to the gate terminal of the source-follower transistor 412 which can degrade the pixel signals generated for dim regions in a captured scene. Thus, for dim regions in a captured scene, the gain control signal G_CTRL may be de-asserted to turn off the gain control transistor 416. The discussion now turns in greater detail to the double MIM capacitor 418.

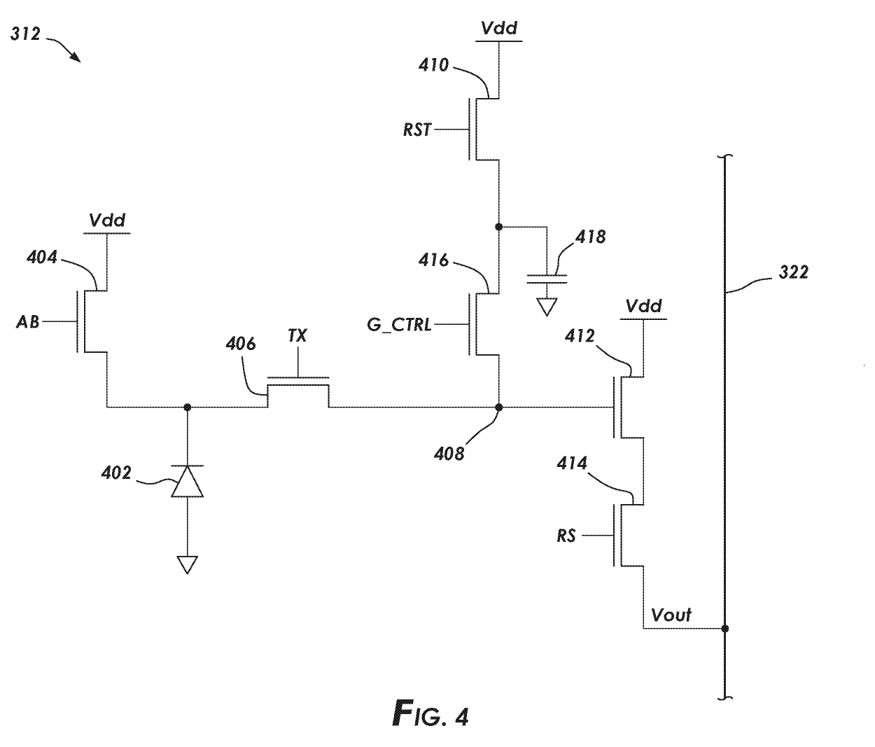

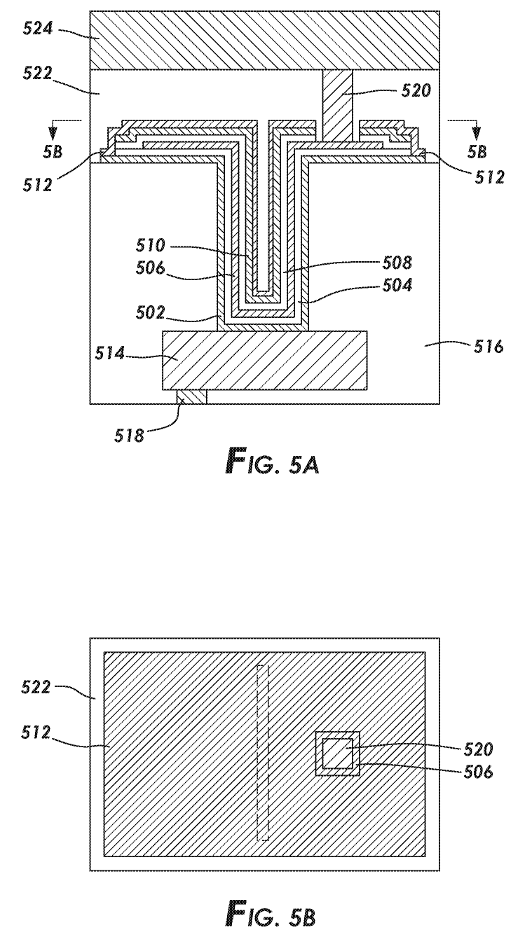

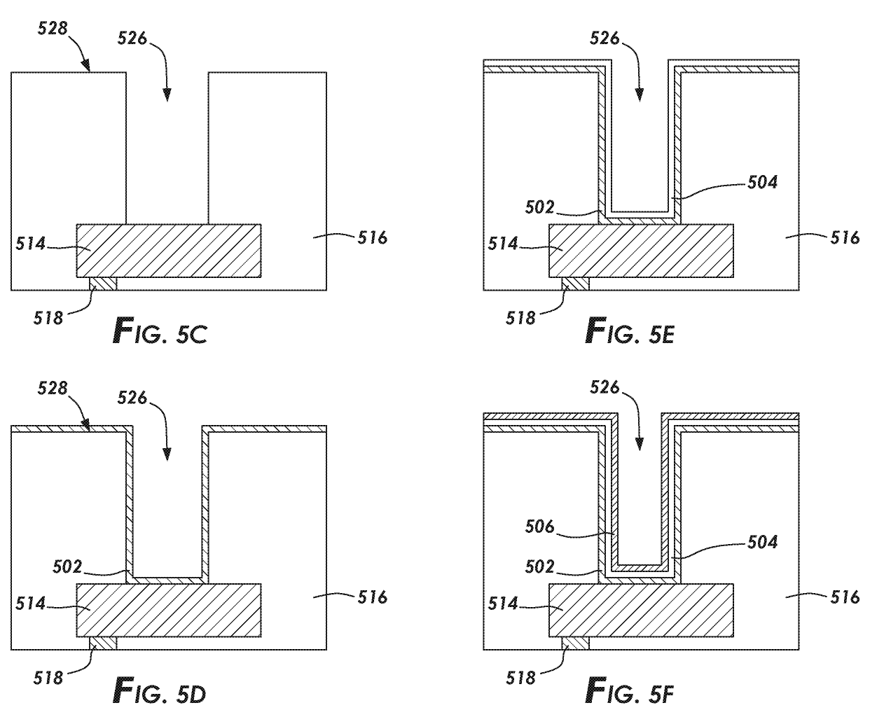

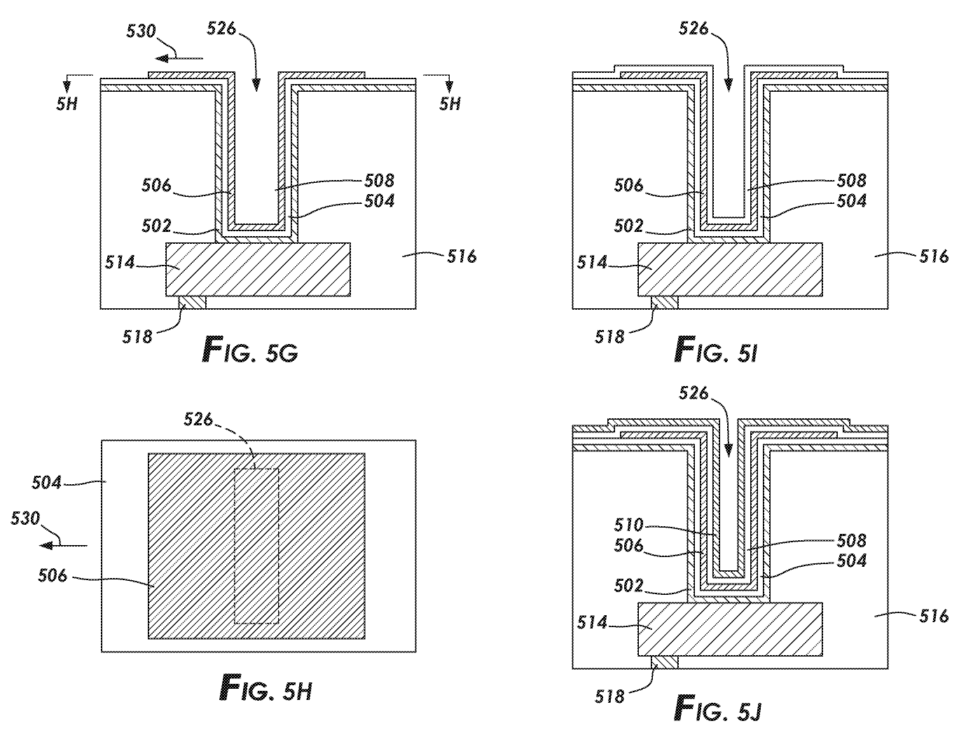

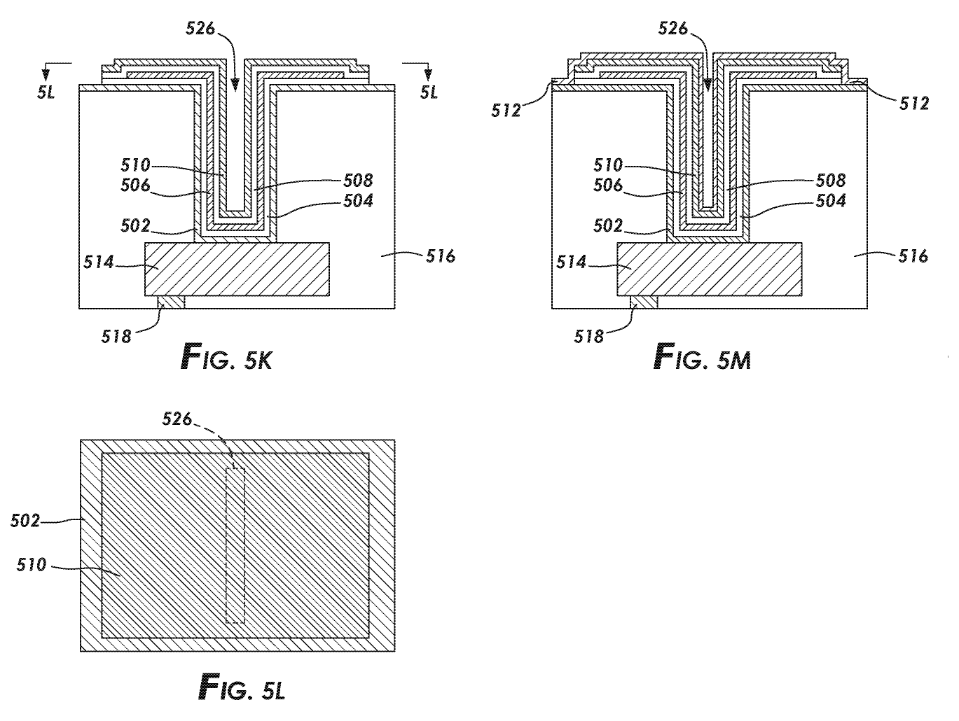

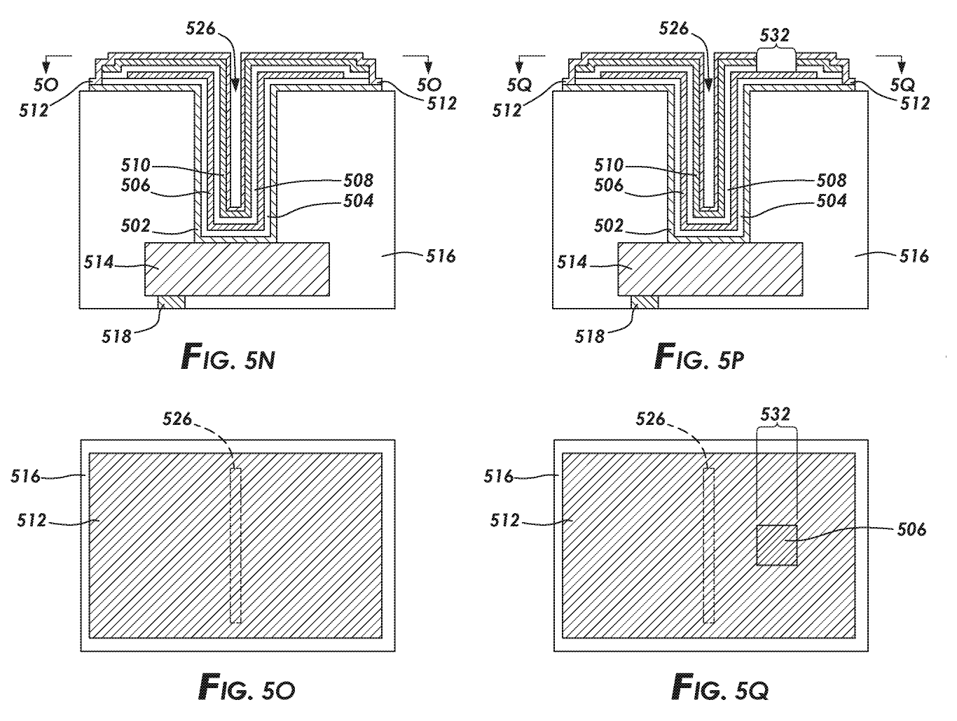

FIG. 5A is a side cross-sectional view of an example of a double MIM capacitor with a patterned metal spacer layer. FIG. 5B is a top cross-sectional view taken along line 5B—5B in FIG. 5A. The double MIM capacitor illustrated in FIGS. 5A and 5B includes a bottom electrode layer 502, a lower dielectric layer 504, a middle electrode layer 506, an upper dielectric layer 508, a top electrode layer 510, and a patterned metal spacer layer 512. In relation to layers, the terms “top,” “middle,” “bottom,” “upper,” and “lower” are used herein solely to orient the reader. These locational terms do not have any relationship to the direction of the force of gravity. In some implementations, the bottom electrode layer 502 comprises tantalum nitride, titanium nitride, or a combination thereof. In some implementations, the middle electrode layer 506, the top electrode layer 510, and the patterned metal spacer layer 512 include titanium nitride. The lower dielectric layer 504 and the upper dielectric layer 508 comprise a high-K dielectric material. The bottom electrode layer 502, the lower dielectric layer 504, the middle electrode layer 506, the upper dielectric layer 508, and the top electrode layer 510 are stacked on each other. The lower dielectric layer 504 separates the bottom electrode layer 502 and the middle electrode layer 506. The upper dielectric layer 508 separates the middle electrode layer 506 and the top electrode layer 510.

A portion of the bottom electrode layer 502 contacts a lower conductive layer 514. The lower conductive layer 514 (one example of a “first conductive layer”) comprises a conductive metal such as copper. The lower conductive layer 514 is positioned within a lower dielectric film layer 516. The lower dielectric film layer 516 comprises a dielectric material such as silicon dioxide. The lower conductive layer 514 is electrically coupled to the floating diffusion 408 by a first via 518. A second via 520 is patterned through an upper dielectric film layer 522 to electrically couple the middle electrode layer 506 to an upper conductive layer 524. The upper dielectric film layer 522 comprises a dielectric material such as silicon dioxide. The upper conductive layer 524 (one example of a “second conductive layer”) comprises a conductive metal such as copper. The upper conductive layer 524 is electrically coupled to a power terminal of the image sensor 106. For example, the upper conductive layer 524 may be electrically coupled to a power supply voltage, a ground terminal, or a common terminal of the image sensor 106. The patterned metal spacer layer 512 electrically couples the bottom electrode layer 502 and the top electrode layer 510. Thus, a first MIM capacitor is formed by the bottom electrode layer 502, the lower dielectric layer 504, and the middle electrode layer 506, and a second MIM capacitor is formed by the middle electrode layer 506, the upper dielectric layer 508, and the top electrode layer 510.

FIGS. 5C-5Q are views during different steps of an example of a process for manufacturing the double MIM capacitor illustrated in FIGS. 5A and 5B. In the side cross-sectional view of FIG. 5C, a trench 526 is etched in the lower dielectric film layer 516 between a top side 528 of the lower dielectric film layer 516 and the lower conductive layer 514. In the side cross-sectional view of FIG. 5D, the bottom electrode layer 502 (one example of a “first electrode layer”) is formed along an inner border of the trench 526 and extending outward or away from an open end of the trench 526 along the top side 528 of the lower dielectric film layer 516. A portion of the bottom electrode layer 502 is directly connected to the lower conductive layer 514 because the trench 526 lands on a surface of the lower conductive layer 514. The direct connection between the bottom electrode layer 502 and the lower conductive layer 514 provides lower resistance for the bottom electrode layer 502 than if the bottom electrode layer 502 is indirectly coupled to the lower conductive layer 514, for example, by a via. In the side cross-sectional view of FIG. 5E, the lower dielectric layer 504 (one example of a “first dielectric layer”) is formed over the bottom electrode layer 502. In the side cross-sectional view of FIG. 5F, the middle electrode layer 506 (one example of a “second electrode layer”) is formed over the lower dielectric layer 504.

In the side cross-sectional view of FIG. 5G, the middle electrode layer 506 is patterned such that the middle electrode layer 506 extends away from the open end of the trench 526 for lengths that are shorter than the bottom electrode layer 502 and the lower dielectric layer 504. FIG. 5H is a top cross-sectional view taken along line 5H—5H in FIG. 5G. As illustrated in FIGS. 5G and 5H, the middle electrode layer 506 is patterned such that the middle electrode layer 506 extends away from the open end of the trench 526 in a direction (shown by arrow 530) along the top side 528 of the lower dielectric film layer 516 for a length that is shorter than the bottom electrode layer 502 and the lower dielectric layer 504. In the side cross-sectional view of FIG. 5I, the upper dielectric layer 508 (one example of a “second dielectric layer”) is formed over the middle electrode layer 506 and a portion of the lower dielectric layer 504. In the side cross-sectional view of FIG. 5J, the top electrode layer 510 (one example of a “third electrode layer”) is formed over the upper dielectric layer 508.

In the side cross-sectional view of FIG. 5K, the lower dielectric layer 504, the upper dielectric layer 508, and the top electrode layer 510 are patterned. FIG. 5L is a top cross-sectional view taken along line 5L—5L in FIG. 5K. As illustrated in FIGS. 5K and 5L, the lower dielectric layer 504, the upper dielectric layer 508, and the top electrode layer 510 are patterned to reveal the bottom electrode layer 502. In the side cross-sectional view of FIG. 5M, the patterned metal spacer layer 512 is formed over the top electrode layer 510 and the bottom electrode layer 502.

In the side cross-sectional view of FIG. 5N, the bottom electrode layer 502, the top electrode layer 510, and the patterned metal spacer layer 512 are patterned. FIG. 5O is a top cross-sectional view taken along line 5O—5O in FIG. 5N. As illustrated in FIGS. 5N and 5O, the bottom electrode layer 502 and the patterned metal spacer layer 512 are patterned to reveal the lower dielectric film layer 516. In the side cross-sectional view of FIG. 5P, the upper dielectric layer 508, the top electrode layer 510, and the patterned metal spacer layer 512 are patterned. FIG. 5Q is a top cross-sectional view taken along line 5Q—5Q in FIG. 5P. As illustrated in FIGS. 5P and 5Q, the upper dielectric layer 508, the top electrode layer 510, and the patterned metal spacer layer 512 are patterned on the right side to reveal a portion 532 of the middle electrode layer 506. Returning to FIGS. 5A and 5B, the second via 520 is formed to electrically couple the middle electrode layer 506 to the upper conductive layer 524.

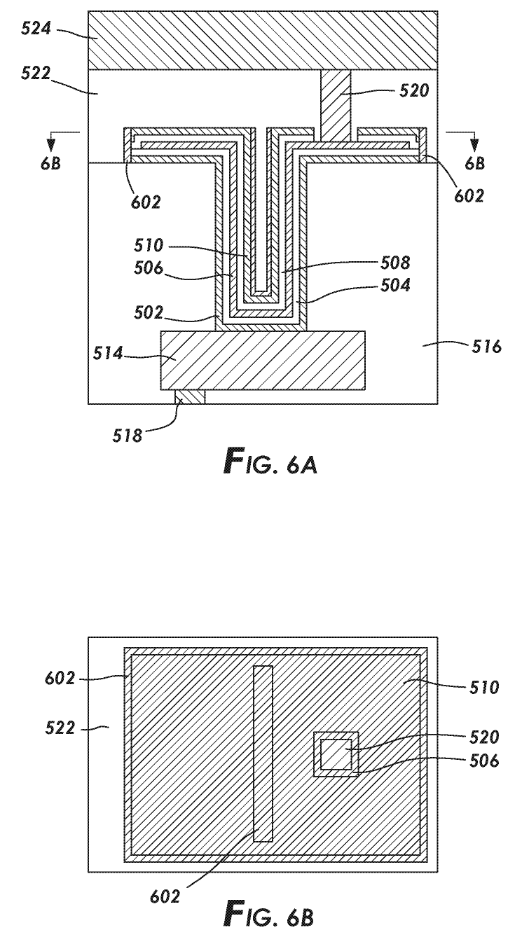

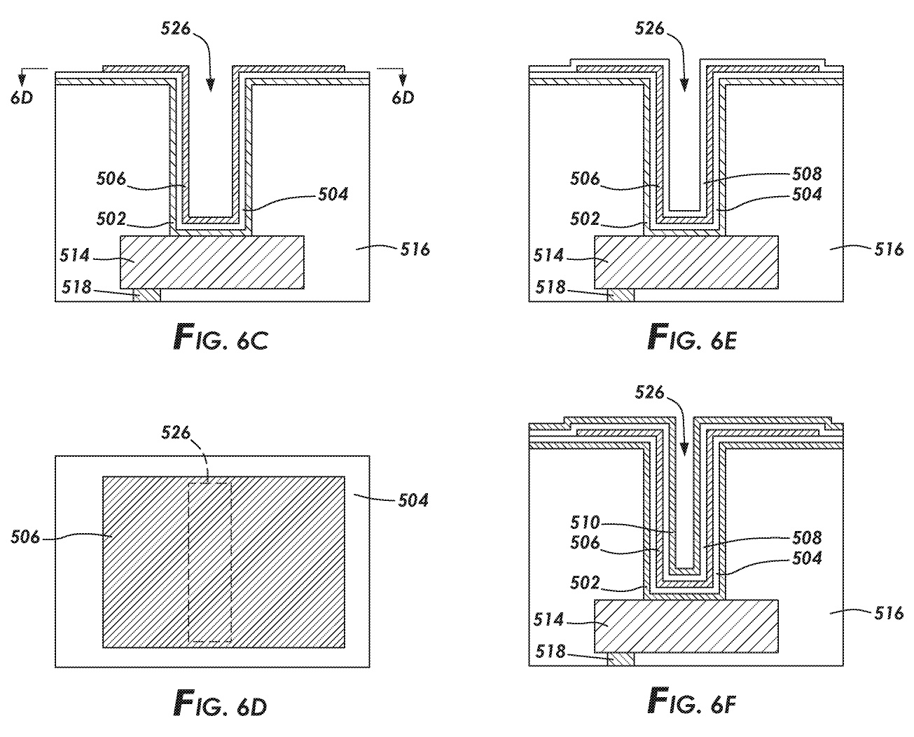

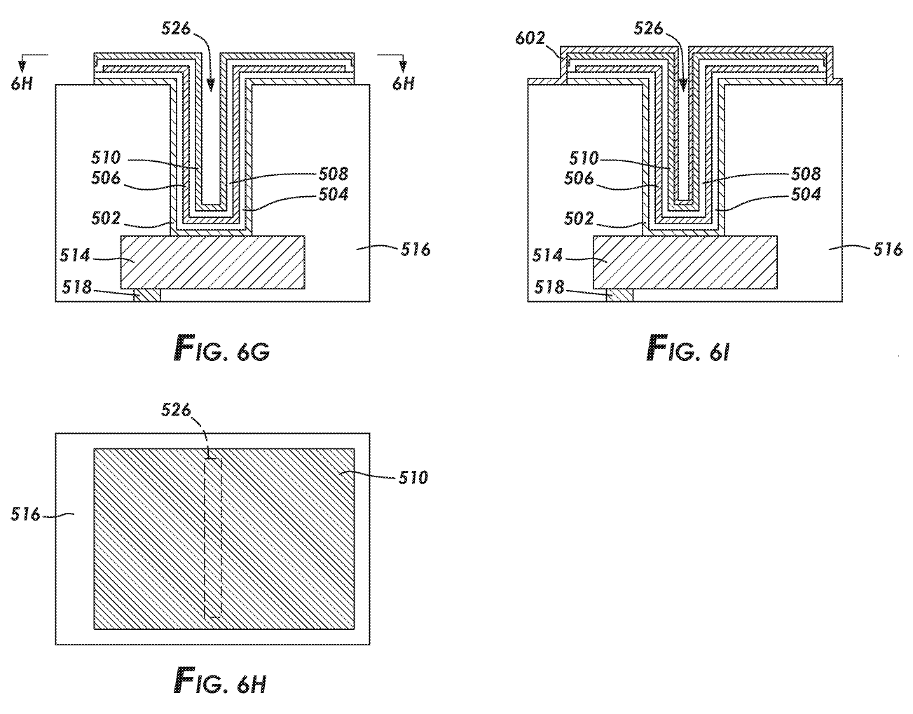

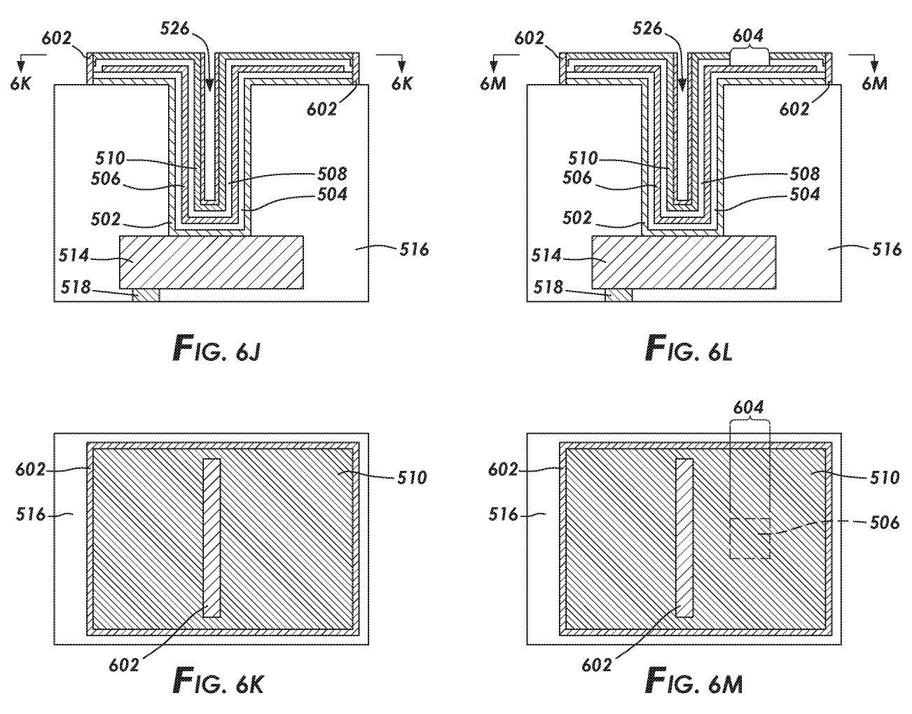

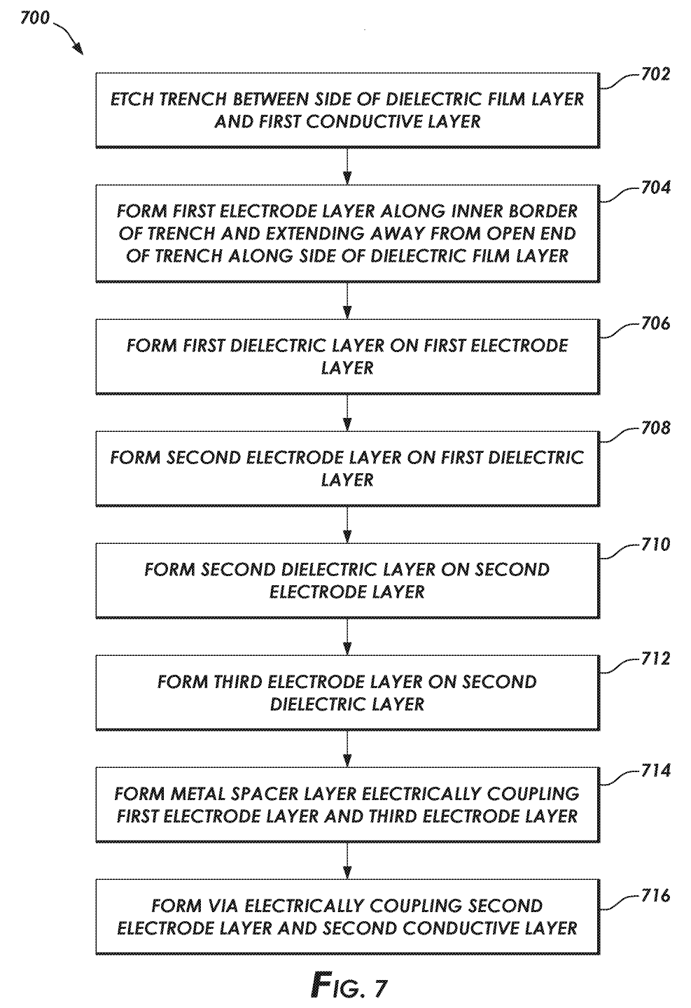

FIG. 6A is a side cross-sectional view of an example of the double MIM capacitor with a blanket metal spacer layer. FIG. 6B is a top cross-sectional view taken along line 6B—6B in FIG. 6A. As illustrated in FIGS. 6A and 6B, a blanket metal spacer layer 602 is blanketed around the bottom electrode layer 502 and the top electrode layer 510 to electrically couple the bottom electrode layer 502 and the top electrode layer 510.

FIGS. 6C-6M are views during different steps of an example of a process for manufacturing the double MIM capacitor illustrated in FIGS. 6A and 6B. The process begins using the same steps as described above in relation to FIGS. 5C-5F. Then, in the side cross-sectional view of FIG. 6C, the middle electrode layer 506 is patterned. FIG. 6D is a top cross-sectional view taken along line 6D—6D in FIG. 6C. As illustrated in FIGS. 6C and 6D, the middle electrode layer 506 is patterned to reveal the lower dielectric layer 504. In the side cross-sectional side view of FIG. 6E, the upper dielectric layer 508 is formed over the middle electrode layer 506 and a portion of the lower dielectric layer 504. In the side cross-sectional view of FIG. 6F, the top electrode layer 510 is formed over the upper dielectric layer 508.

In the side cross-sectional view of FIG. 6G, the bottom electrode layer 502, the lower dielectric layer 504, the upper dielectric layer 508, and the top electrode layer 510 are patterned. FIG. 6H is a top cross-sectional view taken along line 6H—6H in FIG. 6G. As illustrated in FIGS. 6G and 6H, the bottom electrode layer 502, the lower dielectric layer 504, the upper dielectric layer 508, and the top electrode layer 510 are patterned to reveal the lower dielectric film layer 516. In the side cross-sectional view of FIG. 6I, the blanket metal spacer layer 602 is formed over the top electrode layer 510 and over the revealed portion of the lower dielectric film layer 516.

In the side cross-sectional view of FIG. 6J, the blanket metal spacer layer 602 is patterned. FIG. 6K is a top cross-sectional view taken along line 6K—6K in FIG. 6J. As illustrated in FIGS. 6J and 6K, the blanket metal spacer layer 602 is patterned to reveal the lower dielectric film layer 516. In the side cross-sectional view of FIG. 6L, the upper dielectric layer 508 and the top electrode layer 510 are patterned on the right side. FIG. 6M is a top cross-sectional view taken along line 6M—6M in FIG. 6L. As illustrated in FIGS. 6L and 6M, the upper dielectric layer 508 and the top electrode layer 510 are patterned on the right side to reveal a portion 604 of the middle electrode layer 506. Returning to FIGS. 6A and 6B, the second via 520 is formed to electrically couple the middle electrode layer 506 to the upper conductive layer 524.

FIG. 7 is a flow diagram of an example of a method 700 for fabricating a double MIM capacitor for a pixel of an image sensor in accordance with some implementations. For simplicity of explanation, the method 700 is depicted in FIG. 7 and described as a series of operations. However, the operations can occur in various orders and/or concurrently, and/or with other operations not presented and described herein. At block 702, a trench is etched between a side of a dielectric film layer and a first conductive layer. For example, as illustrated in FIG. 5C, a trench 526 is etched between a top side 528 of the lower dielectric film layer 516 and the lower conductive layer 514. As described above, the lower conductive layer 514 is positioned within the lower dielectric film layer 516 and is electrically coupled to the floating diffusion 408 by the first via 518. At block 704, a first electrode layer is formed along an inner border of the trench and extending outward from an open end of the trench along the side of the dielectric film layer. For example, as illustrated in FIG. 5D, the bottom electrode layer 502 is formed along the inner border of the trench 526 and extends outward from the open end of the trench 526 along the top side 528 of the lower dielectric film layer 516. At block 706, a first dielectric layer is formed on the first electrode layer. For example, as illustrated in FIG. 5E, the lower dielectric layer 504 is formed on the bottom electrode layer 502. At block 708, a second electrode layer is formed on the first dielectric layer. For example, as illustrated in FIG. 5F, the middle electrode layer 506 is formed on the lower dielectric layer 504. At block 710, a second dielectric layer is formed on the second electrode layer. For example, as illustrated in FIG. 5I, the upper dielectric layer 508 is formed on the middle electrode layer 506. At block 712, a second electrode layer is formed on the first dielectric layer. For example, as illustrated in FIG. 5J, the top electrode layer 510 is formed on the upper dielectric layer 508. At block 714, a metal spacer layer is formed that electrically couples the first electrode layer and the third electrode layer. For example, as illustrated in FIG. 5P, the patterned metal spacer layer 512 electrically couples the bottom electrode layer 502 and the top electrode layer 510. Further, as illustrated in FIG. 6J, the blanket metal spacer layer 602 electrically couples the bottom electrode layer 502 and the top electrode layer 510. At block 716, a via is formed that electrically couples the second electrode layer and a second conductive layer. For example, as illustrated in FIGS. 5A and 6A, the second via 520 electrically couples the middle electrode layer 506 and the upper conductive layer 524. As described above, the upper conductive layer 524 is electrically coupled to a power terminal of the image sensor 106, such as a power supply voltage, a ground terminal, or a common terminal.

Many of the electrical connections in the drawings are shown as direct couplings having no intervening devices, but not expressly stated as such in the description above. Nevertheless, this paragraph shall serve as antecedent basis in the claims for referencing any electrical connection as “directly coupled” for electrical connections shown in the drawing with no intervening device(s).

The above discussion is meant to be illustrative of the principles and various implementations of the present invention. Numerous variations and modifications will become apparent to those skilled in the art once the above disclosure is fully appreciated. It is intended that the following claims be interpreted to embrace all such variations and modifications.

What is claimed is:

1. A double metal-insulator-metal (MIM) capacitor for a pixel of an image sensor, the double MIM capacitor comprising:
a trench etched between a side of a dielectric film layer and a first conductive layer, wherein the first conductive layer is positioned within the dielectric film layer and is electrically coupled to a floating diffusion of the pixel;
a first electrode layer formed along an inner border of the trench and extending away from an open end of the trench along the side of the dielectric film layer;
a first dielectric layer formed on the first electrode layer;
a second electrode layer formed on the first dielectric layer;
a second dielectric layer formed on the second electrode layer;
a third electrode layer formed on the second dielectric layer;
a metal spacer layer electrically coupling the first electrode layer and the third electrode layer; and
a via electrically coupling the second electrode layer and a second conductive layer, wherein the second conductive layer is electrically coupled to a power terminal of the image sensor.

2. The double MIM capacitor of claim 1, wherein the metal spacer layer is connected to a portion of the first electrode layer that extends outward from the open end of the trench in a direction along the side of the dielectric film layer farther than the third electrode layer, and wherein the metal spacer layer is further connected to an outer border formed by the third electrode layer, the first dielectric layer, and the second dielectric layer.

3. The double MIM capacitor of claim 2, wherein the direction is a first direction, wherein the via is connected to a portion of the second electrode layer that extends outward from the open end of the trench in a second direction along the side of the dielectric film layer farther than the third electrode layer, and wherein the second direction is opposite the first direction.

4. The double MIM capacitor of claim 1, wherein the first electrode layer extends outward from the open end of the trench in a direction along the side of the dielectric film layer for a first length, wherein the third electrode layer extends outward from the open end of the trench in the direction along the side of the dielectric film layer for a second length shorter than the first length, and wherein the second electrode layer extends outward from the open end of the trench in the direction along the side of the dielectric film layer for a third length shorter than the second length.

5. The double MIM capacitor of claim 1, wherein the metal spacer layer is connected to an outer border formed by the first electrode layer, the third electrode layer, the first dielectric layer, and the second dielectric layer.

6. The double MIM capacitor of claim 5, wherein portions of the third electrode layer and the second dielectric layer that extend along the side of the dielectric film layer are removed to reveal a portion of the second electrode layer, and wherein the via is connected to the revealed portion of the second electrode layer.

7. The double MIM capacitor of claim 5, wherein the first electrode layer extends outward from the open end of the trench in a direction along the side of the dielectric film layer for a first length, wherein the third electrode layer extends outward from the open end of the trench in the direction along the side of the dielectric film layer for a second length about equal to the first length, and wherein the second electrode layer extends outward from the open end of the trench in the direction along the side of the dielectric film layer for a third length shorter than the second length.

8. A pixel of an image sensor, the pixel comprising:
a dielectric film layer;
a floating diffusion;
a lower conductive layer positioned within the dielectric film layer and electrically coupled to the floating diffusion;
an upper conductive layer electrically coupled to a power terminal; and
a double metal-insulator-metal (MIM) capacitor including:
a trench etched between a side of the dielectric film layer and the lower conductive layer,
three stacked electrode layers formed along an inner border of the trench and extending outward from an open end of the trench along the side of the dielectric film layer,
two dielectric layers separating the three stacked electrode layers,
a metal spacer layer electrically coupling a top electrode layer and a bottom electrode layer of the three stacked electrode layers, and
a via electrically coupling a middle electrode layer of the three stacked electrode layers to the upper conductive layer.

9. The pixel of claim 8, wherein the metal spacer layer is connected to a portion of the bottom electrode layer that extends outward from the open end of the trench in a direction along the side of the dielectric film layer farther than the top electrode layer, and wherein the metal spacer layer is further connected to an outer border formed by the top electrode layer and the two dielectric layers.

10. The pixel of claim 9, wherein the direction is a first direction, wherein the via is connected to a portion of the middle electrode layer that extends outward from the open end of the trench in a second direction along the side of the dielectric film layer farther than the top electrode layer, and wherein the second direction is opposite the first direction.

11. The pixel of claim 8, wherein the bottom electrode layer extends outward from the open end of the trench in a direction along the side of the dielectric film layer for a first length, wherein the top electrode layer extends outward from the open end of the trench in the direction along the side of the dielectric film layer for a second length shorter than the first length, and wherein the middle electrode layer extends outward from the open end of the trench in the direction along the side of the dielectric film layer for a third length shorter than the second length.

12. The pixel of claim 8, wherein the metal spacer layer is connected to an outer border formed by the top electrode layer, the bottom electrode layer, and the two dielectric layers.

13. The pixel of claim 12, wherein portions of the top electrode layer and one of the two dielectric layers that extend along the side of the dielectric film layer are removed to reveal a portion of the middle electrode layer, and wherein the via is connected to the revealed portion of the middle electrode layer.

14. The pixel of claim 12, wherein the bottom electrode layer extends outward from the open end of the trench in a direction along the side of the dielectric film layer for a first length, wherein the top electrode layer extends outward from the open end of the trench in the direction along the side of the dielectric film layer for a second length about equal to the first length, and wherein the middle electrode layer extends outward from the open end of the trench in the direction along the side of the dielectric film layer for a third length shorter than the second length.

15. A method for fabricating a double metal-insulator-metal (MIM) capacitor for a pixel of an image sensor, the method comprising:
etching a trench between a side of a dielectric film layer and a first conductive layer, wherein the first conductive layer is positioned within the dielectric film layer and is electrically coupled to a floating diffusion of the pixel;
forming a first electrode layer along an inner border of the trench and extending outward from an open end of the trench along the side of the dielectric film layer;
forming a first dielectric layer on the first electrode layer;
forming a second electrode layer on the first dielectric layer;
forming a second dielectric layer on the second electrode layer;
forming a third electrode layer on the second dielectric layer;
forming a metal spacer layer that electrically couples the first electrode layer and the third electrode layer; and
forming a via that electrically couples the second electrode layer and a second conductive layer, wherein the second conductive layer is electrically coupled to a power terminal of the image sensor.

16. The method of claim 15, wherein the metal spacer layer is formed over the third electrode layer and a portion of the first electrode layer that extends outward from the open end of the trench in a direction along the side of the dielectric film layer farther than the third electrode layer.

17. The method of claim 16, wherein the direction is a first direction, wherein the via is connected to a portion of the second electrode layer that extends outward from the open end of the trench in a second direction along the side of the dielectric film layer farther than the third electrode layer, and wherein the second direction is opposite the first direction.

18. The method of claim 15, further comprising:
patterning the second electrode layer such that the second electrode layer extends away from the open end of the trench in a direction along the side of the dielectric film layer for a first length shorter than the first electrode layer; and
patterning the third electrode layer such that the third electrode layer extends away from the open end of the trench in the direction along the side of the dielectric film layer for a second length shorter than the first electrode layer and longer than the second electrode layer.

19. The method of claim 15, further comprising:
patterning the second electrode layer such that the second electrode layer extends away from the open end of the trench along the side of the dielectric film layer shorter than the first electrode layer; and
patterning the first electrode layer, the third electrode layer, the first dielectric layer, and the second dielectric layer such that the first electrode layer, the third electrode layer, the first dielectric layer, and the second dielectric layer extend away from the open end of the trench along the side of the dielectric film layer for about a similar length,
wherein the metal spacer layer is formed over the third electrode layer and a portion of the first electrode layer that extends outward from the open end of the trench in a direction along the side of the dielectric film layer farther than the third electrode layer.

20. The method of claim 19, further comprising removing portions of the third electrode layer and the second dielectric layer that extend along the side of the dielectric film layer to reveal a portion of the second electrode layer, wherein the via is connected to the revealed portion of the second electrode layer.
